(19) United States
(12) Patent Application Publication
(10) Pub. No.: US 2024/0275381 A1
(43) Pub. Date: Aug. 15, 2024

(54) BIASING OF RADIO FREQUENCY SWITCHES FOR HOT SWITCHING

(71) Applicant: Skyworks Solutions, Inc., Irvine, CA (US)

(72) Inventors: Yu Zhu, Wellesley, MA (US); Zhan Jiang, Billerica, MA (US); Steven J. Belletete, Littleton, MA (US); Paul T. DiCarlo, Marlborough, MA (US)

(21) Appl. No.: 18/437,539

(22) Filed: Feb. 9, 2024

Related U.S. Application Data
(60) Provisional application No. 63/484,818, filed on Feb. 14, 2023.

(51) Int. Cl. H03K 17/687; H04B 1/00; H04W 88/06

(52) U.S. Cl. CPC H03K 17/6871; H04B 1/0064; H04W 88/06

(57) ABSTRACT

Biasing of radio frequency (RF) switches for hot switching is disclosed. In certain implementations, an RF switch includes a first series switching circuit connected between a first pole and a first throw and a second series switching circuit connected between the first pole and a second throw. Additionally, a control circuit controls the first series switching circuit with a first switch control signal and the second series switching circuit with a second switch control signal to provide a transition of the RF switch from a first state in which the first series switching circuit is turned on and second series switching circuit is turned off to a second state in which the first series switching circuit is turned off and the second series switching circuit is turned on. The control circuit turns on the second series switching circuit before turning off the first series switching circuit when providing the transition.

### CROSS-REFERENCE TO RELATED APPLICATIONS

This application claims the benefit of priority under 35 U.S.C. § 119 of U.S. Provisional Patent Application No. 63/484,818, filed Feb. 14, 2023 and titled “BIASING OF RADIO FREQUENCY SWITCHES FOR HOT SWITCHING,” which is herein incorporated by reference in its entirety.

### BACKGROUND

### Field

Embodiments of the invention relate to electronic systems, and in particular, to radio frequency electronics.

### Description of Related Technology

Radio frequency (RF) communication systems can utilize RF switches to for a variety of purposes, including controlling access of various RF components to antennas. Examples of RF communication systems with one or more RF switches include, but are not limited to, mobile phones, tablets, base stations, network access points, laptops, and wearable electronics. Power amplifiers provide amplification to RF signals, which can have a frequency in the range from about 30 kHz to 300 GHz, for instance, in the range of about 410 MHz to about 7.125 GHz for Fifth Generation (5G) cellular communications in Frequency Range 1 (FR1) or in the range of about 24.250 GHz to about 71.000 GHz for Frequency Range 2 (FR2) of the 5G communication standard.

### SUMMARY

In certain embodiments, the present disclosure relates to a front end system. The front end system includes a radio frequency switch including a first series switching circuit connected between a first pole and a first throw, and a second series switching circuit connected between the first pole and a second throw. The front end system further includes a control circuit configured to control the first series switching circuit with a first switch control signal and the second series switching circuit with a second switch control signal, the control circuit operable to provide a transition of the radio frequency switch from a first state in which the first series switching circuit is turned on and second series switching circuit is turned off to a second state in which the first series switching circuit is turned off and the second series switching circuit is turned on, the control circuit further configured to turn on the second series switching circuit before turning off the first series switching circuit when providing the transition.

In some embodiments, the front end system further includes a power amplifier that is enabled and provides a radio frequency output signal to the first pole during the transition of the radio frequency switch.

In various embodiments, the control circuit is configured to delay an edge of the first switch control signal relative to an edge of the second switch control signal. According to a number of embodiments, the edge of the first switch control signal is a falling edge and the edge of the second switch control signal is a rising edge.

In several embodiments, the control circuit is configured to transition the first switch control signal with a first edge rate and to transition the second switch control signal with a second edge rate, the first edge rate slower than the second edge rate. According to a number of embodiments, the first edge rate is a rising edge rate and the second edge rate is a falling edge rate.

In various embodiments, the radio frequency switch further includes a first shunt switching circuit connected between the first pole and a ground voltage, and a second shunt switching circuit connected between the second pole and the ground voltage. According to several embodiments, the first shunt switching circuit is controlled by the second switch control signal, and the second shunt switch circuit is controlled by the first switch control signal.

In some embodiments, the first series switching circuit includes a first plurality of field-effect transistors connected in series, and the second series switching circuit includes a second plurality of field-effect transistors connected in series.

In several embodiments, the radio frequency switch includes two or more poles including the first pole.

In various embodiments, the radio frequency switch includes three or more throws including the first throw and the second throw.

In some embodiments, the transition includes an intermediate state in which the first series switching circuit is turned on and the second series switching circuit is turned on, the intermediate state occurring between the first state and the second state.

In certain embodiments, the present disclosure relates to a method of radio frequency switch control. The method includes controlling a first series switching circuit of a radio frequency switch using a first control signal from a control circuit, the first series switching circuit connected between a first pole and a first throw of the radio frequency switch. The method further includes controlling a second series switching circuit of the radio frequency switch using a second control signal from the control circuit, the second series switching circuit connected between the first pole of a second throw of the radio frequency switch. The method further includes providing a transition of the radio frequency switch from a first state in which the first series switching circuit is turned on and second series switching circuit is turned off to a second state in which the first series switching circuit is turned off using the control circuit, including turning on the second series switching circuit before turning off the first series switching circuit.

In some embodiments, the method further includes providing a radio frequency output signal from a power amplifier that is enabled to the first pole during the transition of the radio frequency switch.

In various embodiments, the method further includes delaying an edge of the first switch control signal relative to an edge of the second switch control signal. According to a number of embodiments, the edge of the first switch control signal is a falling edge and the edge of the second switch control signal is a rising edge.

In several embodiments, the method further includes transitioning the first switch control signal with a first edge rate and to transition the second switch control signal with a second edge rate, the first edge rate slower than the second edge rate.

In certain embodiments, the present disclosure relates to a mobile device. The mobile device includes a front end system including a radio frequency switch including a first series switching circuit connected between a first pole and a first throw, and a second series switching circuit connected between the first pole and a second throw. The front end system further includes a control circuit configured to control the first series switching circuit with a first switch control signal and the second series switching circuit with a second switch control signal, the control circuit operable to provide a transition of the radio frequency switch from a first state in which the first series switching circuit is turned on and second series switching circuit is turned off to a second state in which the first series switching circuit is turned off and the second series switching circuit is turned on, the control circuit further configured to turn on the second series switching circuit before turning off the first series switching circuit when providing the transition. The mobile device further includes a plurality of antennas including a first antenna connected to the first throw of the radio frequency switch and a second antenna connected to the second throw of the radio frequency switch.

In some embodiments, the front end system further includes a power amplifier that is enabled and provides a radio frequency output signal to the first pole during the transition of the radio frequency switch.

In several embodiments, the control circuit is configured to delay an edge of the first switch control signal relative to an edge of the second switch control signal. According to a number of embodiments, the edge of the first switch control signal is a falling edge and the edge of the second switch control signal is a rising edge.

In various embodiments, the control circuit is configured to transition the first switch control signal with a first edge rate and to transition the second switch control signal with a second edge rate, the first edge rate slower than the second edge rate. According to a number of embodiments, the first edge rate is a rising edge rate and the second edge rate is a falling edge rate.

In some embodiments, the radio frequency switch further includes a first shunt switching circuit connected between the first pole and a ground voltage, and a second shunt switching circuit connected between the second pole and the ground voltage. According to a number of embodiments, the first shunt switching circuit is controlled by the second switch control signal, and the second shunt switch circuit is controlled by the first switch control signal.

In various embodiments, the first series switching circuit includes a first plurality of field-effect transistors connected in series, and the second series switching circuit includes a second plurality of field-effect transistors connected in series.

In several embodiments, the radio frequency switch includes two or more poles including the first pole.

In various embodiments, the radio frequency switch includes three or more throws including the first throw and the second throw.

In some embodiments, the transition includes an intermediate state in which the first series switching circuit is turned on and the second series switching circuit is turned on, the intermediate state occurring between the first state and the second state.

### BRIEF DESCRIPTION OF THE DRAWINGS

FIG. 1 is a schematic diagram of one example of a communication network.

FIG. 2 is a schematic diagram of one embodiment of an integrated circuit (IC).

FIG. 3 is a schematic diagram of one embodiment of a power amplifier system.

FIG. 4A is a graph of one example of power versus time for hot switching of an RF switch.

FIG. 4B is a graph of one example of input impedance versus time for hot switching of an RF switch.

FIG. 4C is a graph of another example of input impedance versus time for hot switching of an RF switch.

FIG. 4D is a graph of biasing an RF switch according to one embodiment.

FIG. 4E is one example of a plot comparing impedance versus time with and without a biasing delay.

FIG. 4F is one example of a graph comparing voltage standing wave ratio (VSWR) versus time with and without a biasing delay.

FIG. 4G is one example of a graph comparing input power versus time with and without a biasing delay.

FIG. 4H is one example of a graph comparing maximum VSWR versus input power with and without a biasing delay.

FIG. 5A is a graph of biasing an RF switch according to another embodiment.

FIG. 5B is one example of a plot comparing impedance versus time for two different biasing rise times.

FIG. 5C is one example of a graph comparing VSWR for two different biasing rise times.

FIG. 5D is one example of a graph comparing input power versus time for two different biasing rise times.

FIG. 6A is a first phase of biasing an RF switch according to one embodiment.

FIG. 6B is a second phase of biasing an RF switch according to one embodiment.

FIG. 6C is a third phase of biasing an RF switch according to one embodiment.

FIG. 7A is a schematic diagram of one example of a single pole multi throw switch.

FIG. 7B is a schematic diagram of one example of a multi pole multi throw switch.

FIG. 8A is a schematic diagram of one embodiment of an RF switch.

FIG. 8B is a schematic diagram of another embodiment of an RF switch.

FIG. 9 is a schematic diagram of one embodiment of a mobile device.

FIG. 10A is a schematic diagram of one embodiment of a packaged module.

FIG. 10B is a schematic diagram of a cross-section of the packaged module of FIG. 10A taken along the lines 10B-10B.

### DETAILED DESCRIPTION OF EMBODIMENTS

The headings provided herein, if any, are for convenience only and do not necessarily affect the scope or meaning of the claimed invention.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

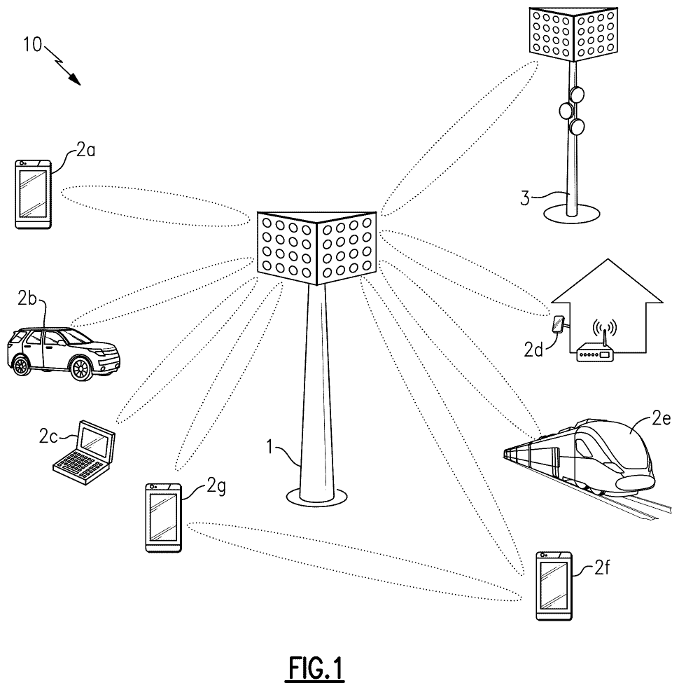

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless- connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

FIG. 2 is a schematic diagram of one embodiment of an integrated circuit (IC) 20. The illustrated IC 20 includes a first pin 15a that receives a power low supply voltage V₁ (for instance, ground) and a second pin 15b that receives a power high supply voltage V₂. Additionally, the illustrated IC 20 further includes RF switches 21, a charge pump 22, and a switch controller 23. Although not illustrated in FIG. 2 for clarity of the figures, the IC 20 typically includes additional pins and circuitry.

The charge pump 22 can be used to generate a charge pump voltage that has a voltage level less than that of the power low supply voltage V₁. The switch controller 23 receives the charge pump voltage, which can be used in part to control the RF switches 21.

For example, the illustrated IC 20 can represent a front-end module (FEM), and the RF switches 21 can include n-type metal oxide semiconductor (NMOS) switch transistors including gates that are biased to a voltage level of the charge pump voltage when in the off state. Controlling the gate voltage of an NMOS switch transistor to a voltage below a power low supply voltage in the off state can increase off state impedance, which can enhance isolation in multi-band applications.

When the NMOS switch transistors operate in the on state, the NMOS switch transistors can be biased to any suitable voltage level, such as the voltage level of the power high supply voltage V₂. In certain configurations, the power high supply voltage V₂ can correspond to a regulated voltage generated by an on-chip or off-chip regulator. Generating the power high supply voltage V₂ using a regulator can aid in controlling NMOS switch transistors operating in the on-state with a voltage level that is relatively constant with respect to temperature, battery voltage level, and/or current loading.

In certain configurations, the IC 20 is fabricated using a silicon on insulator (SOI) process, and the RF switches 21 can include SOI transistors. However, other configurations are possible. The IC 20 can be implemented with biasing in accordance with any of the embodiments herein.

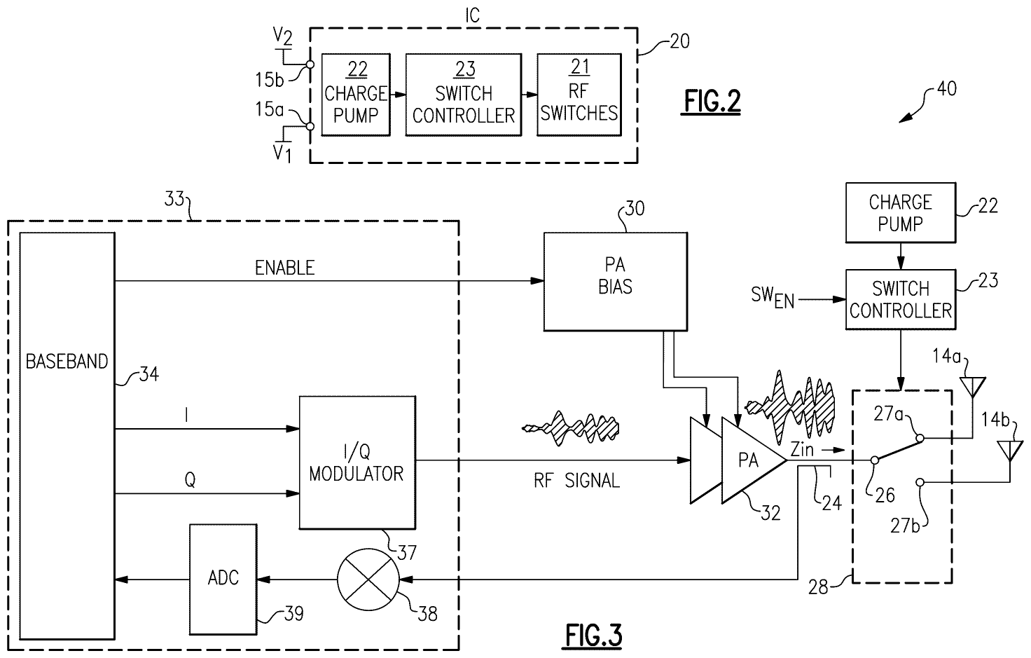

FIG. 3 is a schematic diagram of one embodiment of a power amplifier system 40. The illustrated power amplifier system 40 includes an RF switch 28 that includes a first pole 26, a first throw 27a, and a second throw 27b. The illustrated power amplifier system 40 further includes a first antenna 14a, a second antenna 14b, a charge pump 22, a switch controller 23, a directional coupler 24, a power amplifier bias circuit 30, a power amplifier 32, and a transmitter 33. The illustrated transmitter 33 includes a baseband processor 34, an I/Q modulator 37, a mixer 38, and an analog-to-digital converter (ADC) 39.

The baseband processor 34 can be used to generate an in-phase (I) signal and a quadrature-phase (Q) signal, which can be used to represent a sinusoidal wave or signal of a desired amplitude, frequency, and phase. For example, the I signal can be used to represent an in-phase component of the sinusoidal wave and the Q signal can be used to represent a quadrature component of the sinusoidal wave, which can be an equivalent representation of the sinusoidal wave. In certain implementations, the I and Q signals can be provided to the I/Q modulator 37 in a digital format. The baseband processor 34 can be any suitable processor configured to process a baseband signal. For instance, the baseband processor 34 can include a digital signal processor, a microprocessor, a programmable core, or any combination thereof. Moreover, in some implementations, two or more baseband processors 34 can be included in the power amplifier system 40.

The I/Q modulator 37 can be configured to receive the I and Q signals from the baseband processor 34 and to process the I and Q signals to generate an RF signal. For example, the I/Q modulator 37 can include DACs configured to convert the I and Q signals into an analog format, mixers for upconverting the I and Q signals to radio frequency, and a signal combiner for combining the upconverted I and Q signals into an RF signal suitable for amplification by the power amplifier 32. In certain implementations, the I/Q modulator 37 can include one or more filters configured to filter frequency content of signals processed therein.

The power amplifier bias circuit 30 can receive an enable signal ENABLE from the baseband processor 34 and can use the enable signal ENABLE to generate one or more bias signals for the power amplifier 32. The power amplifier 32 can receive the RF signal from the I/Q modulator 37.

The switch controller 23 controls the RF switch 28. For example, the switch controller 23 can be used to transition the RF switch 28 from connecting an output of the power amplifier 32 (which drives the first pole 26) to the first antenna 14a to connecting the output of the power amplifier 32 to the second antenna 14b. To control a state of the RF switching circuit 27, the switch controller 23 can receive a switch enable signal SW_{EN}.

The directional coupler 24 can be positioned between the output of the power amplifier 32 and the first pole 26 of the RF switch 28, thereby allowing an output power measurement of the power amplifier 32 that does not include insertion loss of the RF switch 28. The sensed output signal from the directional coupler 24 can be provided to the mixer 38, which can multiply the sensed output signal by a reference signal of a controlled frequency so as to downshift the frequency content of the sensed output signal to generate a downshifted signal. The downshifted signal can be provided to the ADC 39, which can convert the downshifted signal to a digital format suitable for processing by the baseband processor 34.

By including a feedback path between the output of the power amplifier 32 and the baseband processor 34, the baseband processor 34 can be configured to dynamically adjust the I and Q signals to optimize the operation of the power amplifier system 40. For example, configuring the power amplifier system 40 in this manner can aid in controlling the power added efficiency (PAE) and/or linearity of the power amplifier 32.

In the illustrated configuration, the charge pump 22 provides a charge pump voltage to switch controller 23 used to control the RF switch 28.

As shown in FIG. 3, the power amplifier 32 is presented with an input impedance Zin of the RF switch 28. In certain implementations, the power amplifier system 40 operates with hot switching, in which the power amplifier 32 is enabled and outputting an amplified RF signal while a state of the RF switch 28 is transitioned from connecting the first pole 26 to the first throw 27a to connecting the first pole 26 to the second throw 27b, or vice versa.

Absent compensation, the change in the input impedance Zin during such a transition leads to high input voltage standing wave ratio (VSWR) and a large power reflection due to mismatch.

In certain embodiments herein, a front end system includes an RF switch including a first series switching circuit connected between a first pole and a first throw, and a second series switching circuit connected between the first pole and a second throw. Additionally, a control circuit controls the first series switching circuit with a first switch control signal and the second series switching circuit with a second switch control signal, and is operable to provide a transition of the RF switch from a first state in which the first series switching circuit is turned on and second series switching circuit is turned off to a second state in which the first series switching circuit is turned off and the second series switching circuit is turned on. The control circuit turns on the second series switching circuit before turning off the first series switching circuit when providing the transition.

By biasing the RF switch in this manner, dynamic switch VSWR is improved. For example, such improvement for the dynamic switch VSWR can be achieve in various applications, such as hot switching in which a power amplifier is enabled and drives the first pole of the RF switch during the transition.

In certain implementations, the control circuit operates with a bias time sequence in which OFF-to-ON bias is applied at first, and the ON-to-OFF bias is then applied after a time delay. Additionally, the dynamic switch VSWR is significantly improved by selection of a value of the time delay. Additionally or alternatively, an edge rate (for example, rising edge rate) of the OFF-to-ON bias is selected to be faster than an edge rate (for example, falling edge rate) of the ON-to-OFF bias.

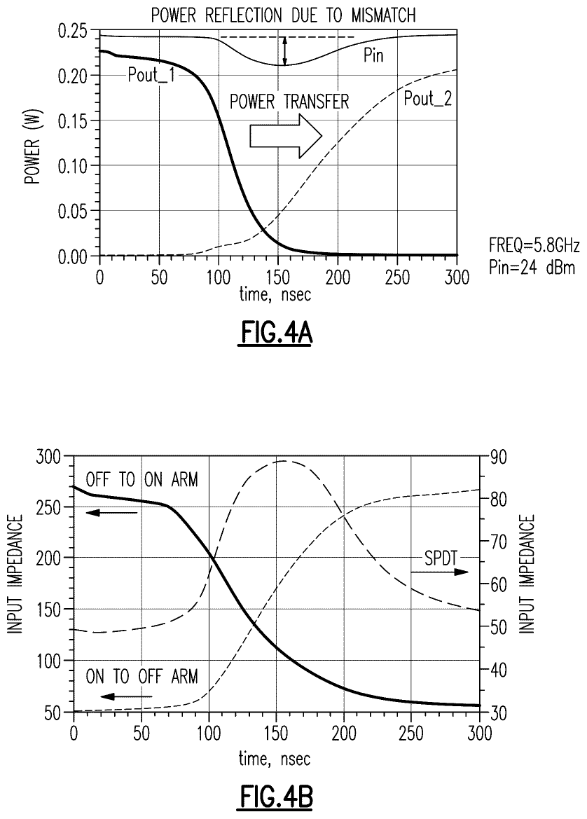

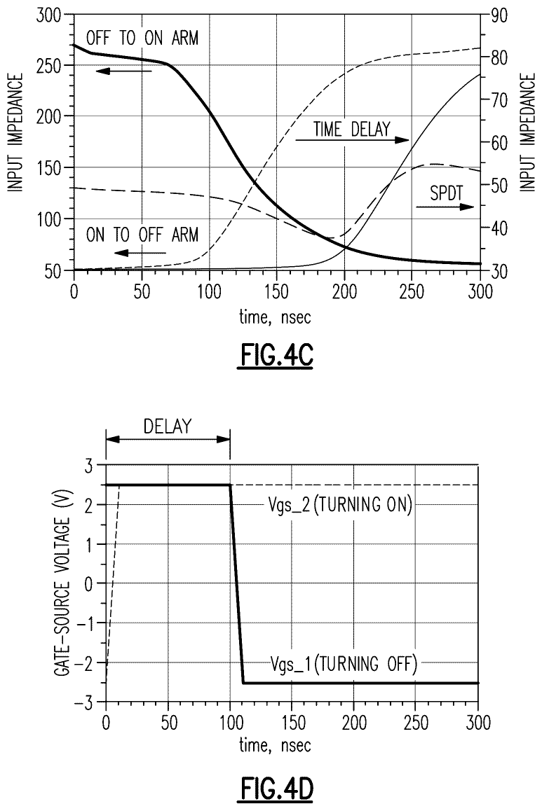

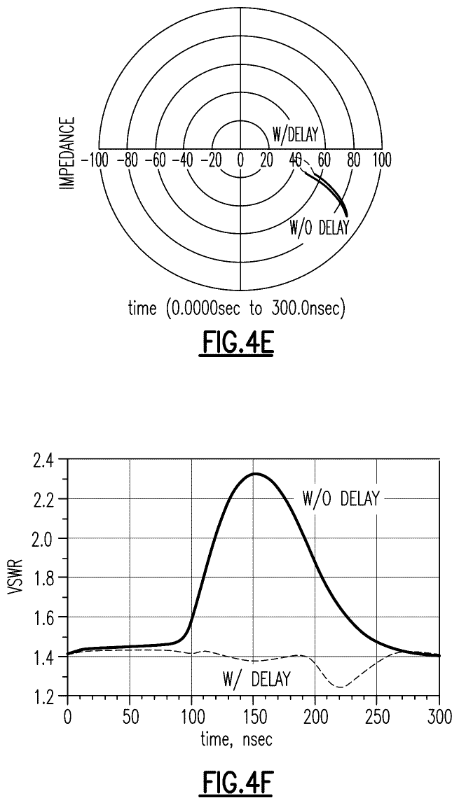

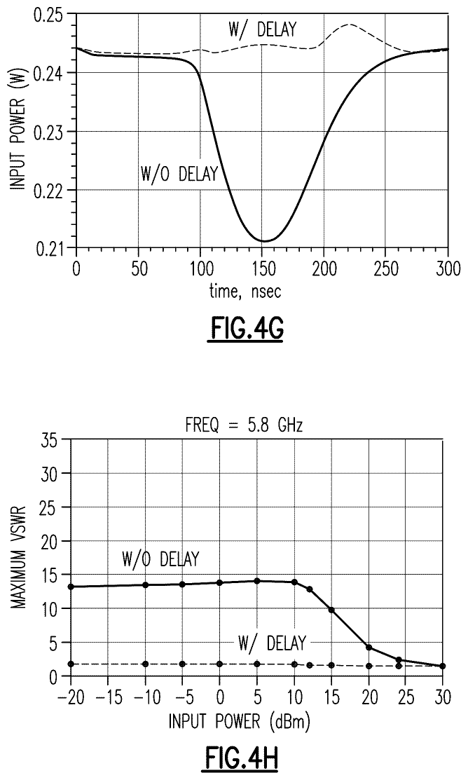

FIG. 4A is a graph of one example of power versus time for hot switching of an RF switch. FIG. 4B is a graph of one example of input impedance versus time for hot switching of an RF switch. In this example, the operating frequency is 5.8 GHz (5 GHz Wi-Fi) and input power (Pin) is 24 dBm.

With reference to FIGS. 4A and 4B, in this example, the OFF-to-ON bias and the ON-to-OFF bias of the RF switch is applied at the same time. As shown in FIGS. 4A and 4B, high input impedance and a large power reflection due to mismatch arises when biasing the RF switch in this manner.

FIG. 4C is a graph of another example of input impedance versus time for hot switching of an RF switch. Similar to FIG. 4B, the graph of FIG. 4C is taken for an example in which operating frequency is 5.8 GHz (5 GHz Wi-Fi) and input power (Pin) is 24 dBm. However, in contrast to FIG. 4B, the graph of FIG. 4C includes a bias time sequence in which OFF-to-ON bias is applied at first, and the ON-to-OFF bias is then applied after a time delay.

As shown by a comparison of FIGS. 4B and 4C, providing the time delay reduces input impedance to the RF switch. This in turn leads to improved VSWR and lower power reflections.

FIG. 4D is a graph of biasing an RF switch according to one embodiment. In this example, a bias time sequence is shown in which OFF-to-ON bias is applied at first, and the ON-to-OFF bias is then applied after a time delay.

FIG. 4E is one example of a plot comparing impedance versus time with and without a biasing delay. As shown in FIG. 4E, providing time delay reduces input impedance to an RF switch.

FIG. 4F is one example of a graph comparing VSWR versus time with and without a biasing delay. As shown in FIG. 4F, providing time delay reduces VSWR.

FIG. 4G is one example of a graph comparing input power versus time with and without a biasing delay. As shown in FIG. 4G, providing time delay reduces power reflections arising from mismatch.

FIG. 4H is one example of a graph comparing maximum VSWR versus input power with and without a biasing delay. As shown in FIG. 4F, providing time delay reduces maximum VSWR for a wide range of input power levels.

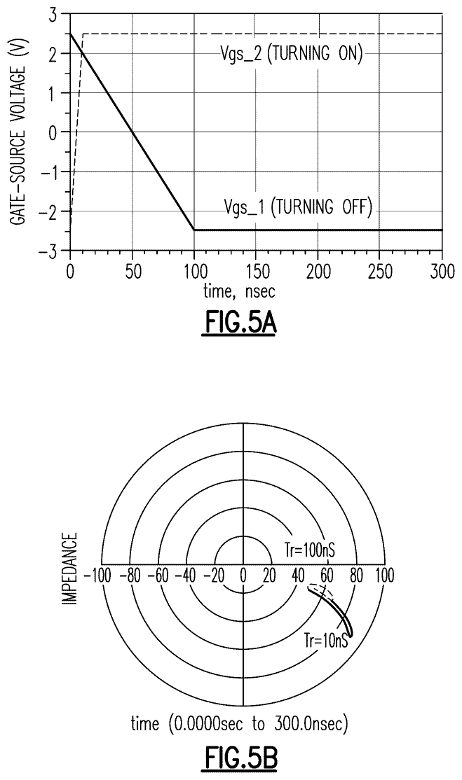

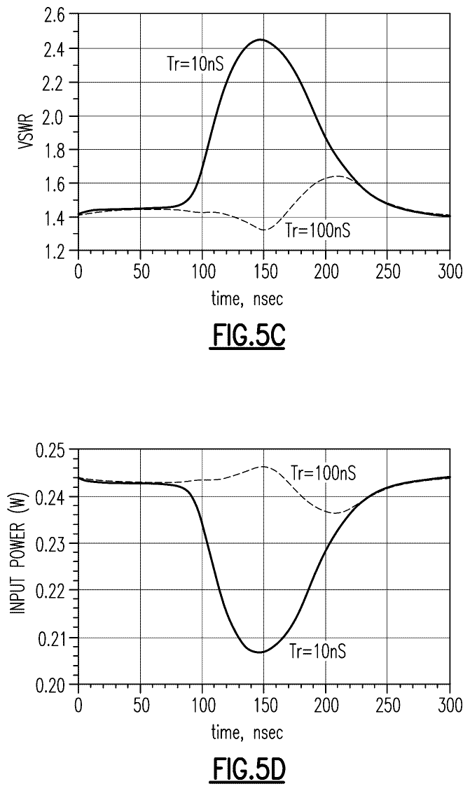

FIG. 5A is a graph of biasing an RF switch according to another embodiment. In this example, a bias time sequence is shown in which a rise time for OFF-to-ON bias is faster than a fall time for ON-to-OFF bias.

FIG. 5B is one example of a plot comparing impedance versus time for two different biasing rise times.

FIG. 5C is one example of a graph comparing VSWR for two different biasing rise times.

FIG. 5D is one example of a graph comparing input power versus time for two different biasing rise times.

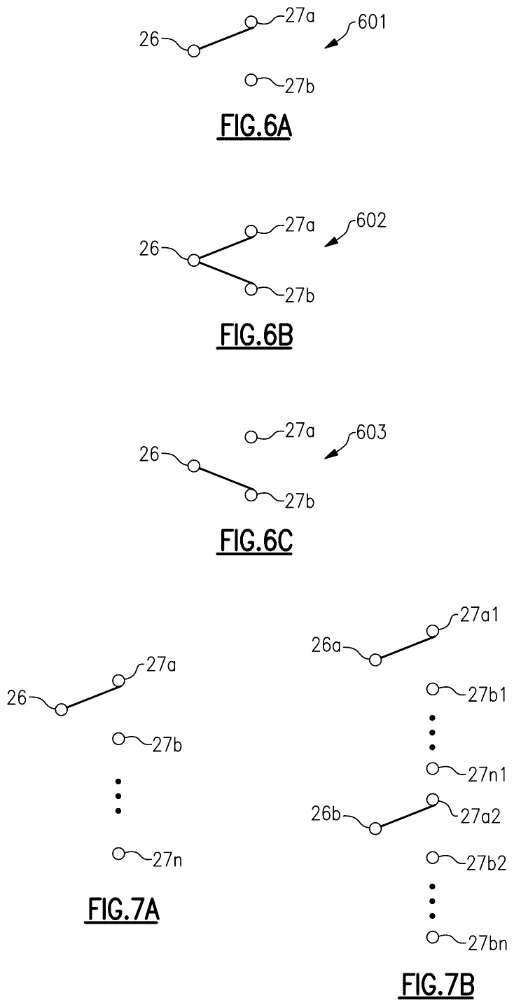

FIG. 6A is a first phase 601 of biasing an RF switch according to one embodiment. FIG. 6B is a second phase 602 of biasing an RF switch according to one embodiment. FIG. 6C is a third phase 603 of biasing an RF switch according to one embodiment.

With reference to FIGS. 6A-6C, an RF switch is transitioned from a first state shown in FIG. 6A in which the RF switch connects a first pole 26 to a first throw 27a to a second state shown in FIG. 6C in which the RF switch connects the first pole 26 to a second throw 27b. As shown in FIG. 6B, during the second phase 601 the RF switch is in a state in which a connection to both the first throw 27a and the second throw 27b is present.

FIG. 7A is a schematic diagram of one example of a single pole multi throw switch. For example, FIG. 7A depicts the pole 26 and throws 27a, 27b, . . . 27n. FIG. 7B is a schematic diagram of one example of a multi pole multi throw switch. For example, FIG. 7B depicts poles 26a/26b and throws 27a1, 27b1, . . . 27n1, 27a2, 27b2, . . . 27n2.

The biasing schemes herein are applicable to RF switches with any number of poles and throws. Thus, although certain embodiments herein are depicted for a single pole double throw (SPDT) switch, the teachings herein are applicable to RF switches with other numbers of poles and/or throws.

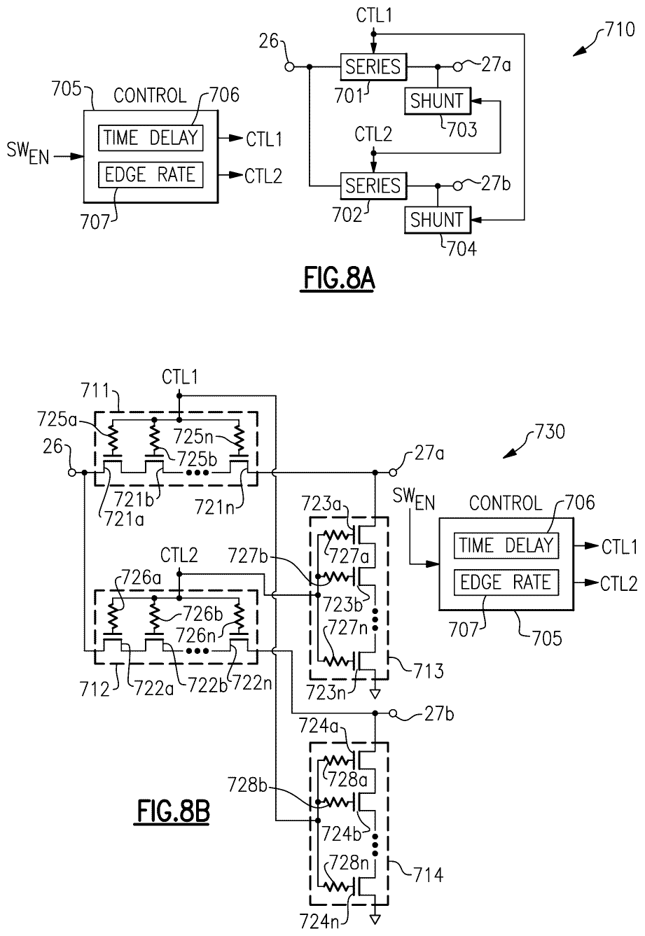

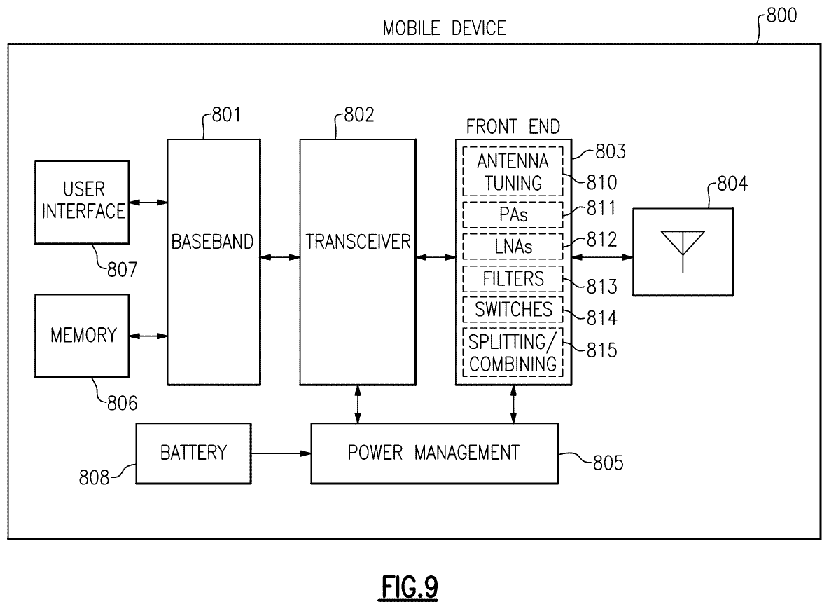

FIG. 8A is a schematic diagram of one embodiment of an RF switch 710. The RF switch includes a pole 26, a first throw 27a, a second throw 27b, a first series switching circuit 701 connected between the pole 26 and the first throw 27a, a second series switching circuit 702 connected between the pole 26 and the second throw 27b, a first shunt switching circuit 703 connected in shunt to the first throw 27a, a second shunt switching circuit 704 connected in shunt to the second throw 27b, and a control circuit 705.

As shown in FIG. 8A, the control circuit 705 receives a switch enable SW_{EN} for controlling a state of the RF switch 710. The control circuit 705 generates a first control signal CTL1 for controlling the first series switching circuit 701 and the second shunt switching circuit 704, and a second control signal CTL for controlling the second series switching circuit 702 and the first shunt switching circuit 703.

In the illustrated embodiment, the control circuit 705 includes at least one of a time delay circuit 706 or an edge rate control circuit 707. The control circuit 705 generates the control signals CTL1 and CTL2 to operate with a bias time sequence in which OFF-to-ON bias is applied at first, and the ON-to-OFF bias is applied after. Such a bias time sequence can be controlled by the time delay circuit 706 for applying a time delay. Additionally or alternatively, an edge rate (for example, rising edge rate) of the OFF-to-ON bias is selected to be faster than an edge rate (for example, falling edge rate) of the ON-to-OFF bias by the edge rate circuit 707.

FIG. 8B is a schematic diagram of another embodiment of an RF switch 730. The RF switch 730 includes a pole 26, a first throw 27a, a second throw 27b, a first series switching circuit 711 connected between the pole 26 and the first throw 27a, a second series switching circuit 712 connected between the pole 26 and the second throw 27b, a first shunt switching circuit 713 connected between the first throw 27a and ground, a second shunt switching circuit 714 connected between the second throw 27b and ground, and a control circuit 705.

The RF switch 730 of FIG. 8B is similar to the RF switch 710 of FIG. 8A, except that the RF switch 730 of FIG. 8B depicts a specific implementation of series switching circuits and shunt switching circuits. For example, the first series switching circuit 711 includes field-effect transistors (FETs) 721a, 721b, . . . 721n in series and gate resistors 725a, 725b, . . . 725n connected between the first control signal CTL1 and the gates of the FETs 721a, 721b, . . . 721n, respectively. Additionally, the second series switching circuit 712 includes FETs 722a, 722b, . . . 722n in series and gate resistors 726a, 726b, . . . 726n connected between the second control signal CTL2 and the gates of the FETs 722a, 722b, . . . 722n, respectively. Furthermore, the first shunt switching circuit 713 includes FETs 723a, 723b, . . . 723n in series and gate resistors 727a, 727b, . . . 727n connected between the second control signal CTL2 and the gates of the FETs 723a, 723b, . . . 723n, respectively. Additionally, the second shunt switching circuit 714 includes FETs 724a, 724b, . . . 724n in series and gate resistors 728a, 728b, . . . 728n connected between the first control signal CTL1 and the gates of the FETs 724a, 724b, . . . 724n, respectively.

FIG. 9 is a schematic diagram of one embodiment of a mobile device 800. The mobile device 800 includes a baseband system 801, a transceiver 802, a front end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 9 as the transceiver 802. In one example, separate components (for instance, separate circuits or dies) can be provided for handling certain types of RF signals.

The front end system 803 aids in conditioning signals transmitted to and/or received from the antennas 804. In the illustrated embodiment, the front end system 803 includes charge pumps 810, power amplifiers (PAs) 811, low noise amplifiers (LNAs) 812, filters 813, switches 814, and signal splitting/combining circuitry 815. The switches 814 can be biased in accordance with any of the embodiments herein.

Accordingly, the front end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 9, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 9, the power management system 805 receives a battery voltage from the battery 808. The battery 808 can be any suitable battery for use in the mobile device 800, including, for example, a lithium-ion battery.

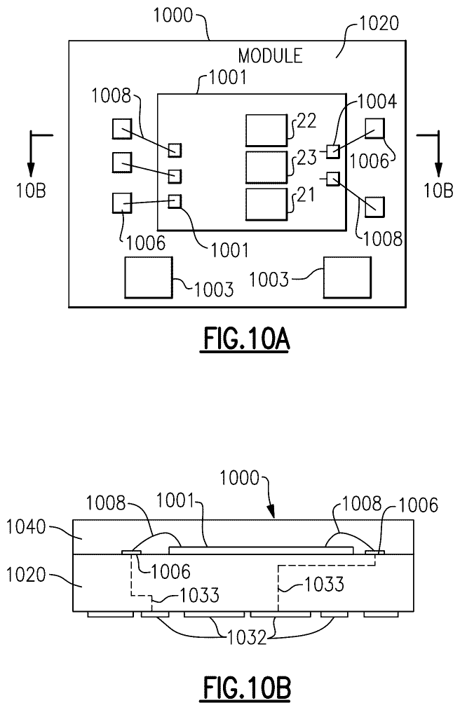

FIG. 10A is a schematic diagram of one embodiment of a packaged module 1000. FIG. 10B is a schematic diagram of a cross-section of the packaged module 1000 of FIG. 10A taken along the lines 10B-10B.

The packaged module 1000 includes an IC or semiconductor die 1001, surface mount components 1003, wirebonds 1008, a package substrate 1020, and encapsulation structure 1040. The package substrate 1020 includes pads 1006 formed from conductors disposed therein. Additionally, the die 1001 includes pads 1004, and the wirebonds 1008 have been used to electrically connect the pads 1004 of the die 1001 to the pads 1006 of the package substrate 1001.

As illustrated in FIGS. 10A and 10B, the die 1001 includes RF switches 21, a charge pump 22, and a switch controller 23, which can be as described earlier. The RF switches 21/switch controller 23 can be implemented with basing in accordance with any of the embodiments herein.

The packaging substrate 1020 can be configured to receive a plurality of components such as the die 1001 and the surface mount components 1003, which can include, for example, surface mount capacitors and/or inductors.

As shown in FIG. 10B, the packaged module 1000 is shown to include a plurality of contact pads 1032 disposed on the side of the packaged module 1000 opposite the side used to mount the die 1001. Configuring the packaged module 1000 in this manner can aid in connecting the packaged module 1000 to a circuit board such as a phone board of a wireless device. The example contact pads 1032 can be configured to provide RF signals, bias signals, power low voltage(s) and/or power high voltage(s) to the die 1001 and/or the surface mount components 1003. As shown in FIG. 10B, the electrically connections between the contact pads 1032 and the die 1001 can be facilitated by connections 1033 through the package substrate 1020. The connections 1033 can represent electrical paths formed through the package substrate 1020, such as connections associated with vias and conductors of a multilayer laminated package substrate.

In some embodiments, the packaged module 1000 can also include one or more packaging structures to, for example, provide protection and/or facilitate handling of the packaged module 1000. Such a packaging structure can include overmold or encapsulation structure 1040 formed over the packaging substrate 1020 and the components and die(s) disposed thereon.

It will be understood that although the packaged module 1000 is described in the context of electrical connections based on wirebonds, one or more features of the present disclosure can also be implemented in other packaging configurations, including, for example, flip-chip configurations.

### Applications

Some of the embodiments described above have provided examples in connection with wireless devices or mobile phones. However, the principles and advantages of the embodiments can be used for any other systems or apparatus that have needs for RF switches.

Such RF switches can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi functional peripheral device, a wrist watch, a clock, etc. Further, the electronic devices can include unfinished products.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A front end system comprising:
a radio frequency switch including a first series switching circuit connected between a first pole and a first throw, and a second series switching circuit connected between the first pole and a second throw; and
a control circuit configured to control the first series switching circuit with a first switch control signal and the second series switching circuit with a second switch control signal, the control circuit operable to provide a transition of the radio frequency switch from a first state in which the first series switching circuit is turned on and second series switching circuit is turned off to a second state in which the first series switching circuit is turned off and the second series switching circuit is turned on, the control circuit further configured to turn on the second series switching circuit before turning off the first series switching circuit when providing the transition.

2. The front end system of claim 1 further comprising a power amplifier that is enabled and provides a radio frequency output signal to the first pole during the transition of the radio frequency switch.

3. The front end system of claim 1 wherein the control circuit is configured to delay an edge of the first switch control signal relative to an edge of the second switch control signal.

4. The front end system of claim 3 wherein the edge of the first switch control signal is a falling edge and the edge of the second switch control signal is a rising edge.

5. The front end system of claim 1 wherein the control circuit is configured to transition the first switch control signal with a first edge rate and to transition the second switch control signal with a second edge rate, the first edge rate slower than the second edge rate.

6. The front end system of claim 5 wherein the first edge rate is a rising edge rate and the second edge rate is a falling edge rate.

7. The front end system of claim 1 wherein the radio frequency switch further includes a first shunt switching circuit connected between the first pole and a ground voltage, and a second shunt switching circuit connected between the second pole and the ground voltage.

8. The front end system of claim 7 wherein the first shunt switching circuit is controlled by the second switch control signal, and the second shunt switch circuit is controlled by the first switch control signal.

9. The front end system of claim 1 wherein the first series switching circuit includes a first plurality of field-effect transistors connected in series, and the second series switching circuit includes a second plurality of field-effect transistors connected in series.

10. The front end system of claim 1 wherein the radio frequency switch includes two or more poles including the first pole.

11. The front end system of claim 1 wherein the radio frequency switch includes three or more throws including the first throw and the second throw.

12. The front end system of claim 1 wherein the transition includes an intermediate state in which the first series switching circuit is turned on and the second series switching circuit is turned on, the intermediate state occurring between the first state and the second state.

13. A method of radio frequency switch control, the method comprising:
controlling a first series switching circuit of a radio frequency switch using a first control signal from a control circuit, the first series switching circuit connected between a first pole and a first throw of the radio frequency switch;
controlling a second series switching circuit of the radio frequency switch using a second control signal from the control circuit, the second series switching circuit connected between the first pole of a second throw of the radio frequency switch; and
providing a transition of the radio frequency switch from a first state in which the first series switching circuit is turned on and second series switching circuit is turned off to a second state in which the first series switching circuit is turned off using the control circuit, including turning on the second series switching circuit before turning off the first series switching circuit.

14. The method of claim 13 further comprising providing a radio frequency output signal from a power amplifier that is enabled to the first pole during the transition of the radio frequency switch.

15. The method of claim 13 further comprising delaying an edge of the first switch control signal relative to an edge of the second switch control signal.

16. The method of claim 15 wherein the edge of the first switch control signal is a falling edge and the edge of the second switch control signal is a rising edge.

17. The method of claim 13 further comprising transitioning the first switch control signal with a first edge rate and to transition the second switch control signal with a second edge rate, the first edge rate slower than the second edge rate.

18. A mobile device comprising:
a front end system including a radio frequency switch including a first series switching circuit connected between a first pole and a first throw, and a second series switching circuit connected between the first pole and a second throw, the front end system further including a control circuit configured to control the first series switching circuit with a first switch control signal and the second series switching circuit with a second switch control signal, the control circuit operable to provide a transition of the radio frequency switch from a first state in which the first series switching circuit is turned on and second series switching circuit is turned off to a second state in which the first series switching circuit is turned off and the second series switching circuit is turned on, the control circuit further configured to turn on the second series switching circuit before turning off the first series switching circuit when providing the transition; and
a plurality of antennas including a first antenna connected to the first throw of the radio frequency switch and a second antenna connected to the second throw of the radio frequency switch.

19. The mobile device of claim 18 wherein the front end system further includes a power amplifier that is enabled and provides a radio frequency output signal to the first pole during the transition of the radio frequency switch.

20. The mobile device of claim 18 wherein the transition includes an intermediate state in which the first series switching circuit is turned on and the second series switching circuit is turned on, the intermediate state occurring between the first state and the second state.
